(19) United States
(12) Patent Application Publication
(10) Pub. No.: US 2009/0008260 A1
(43) Pub. Date: Jan. 8, 2009

(54) Method For Manufacturing Embossed Conductive Clothes

(75) Inventor: Feng-Chang Chang, Touliu (TW)

Correspondence Address: CONNOLLY BOVE LODGE & HUTZ, LLP, P O BOX 2207, WILMINGTON, DE, 19899, US

(73) Assignee: Formosa Taffeta Co., Ltd., Touliu (TW)

(21) Appl. No.: 12/167,278

(22) Filed: Jul. 3, 2008

(30) Foreign Application Priority Data
Jul. 5, 2007 (TW) 096124486

(51) Int. Cl. B05D 5/12; B05D 3/12; C23C 14/34; C25D 5/34; B05D 3/10

(52) U.S. Cl. 205/205; 427/58; 427/121; 427/123; 427/125; 427/124; 204/192.12

(57) ABSTRACT

The present invention provides a method for manufacturing embossed conductive cloth, which comprises the steps of (a) providing cloth made of natural fibers or artificial fibers; (b) embossing the cloth to form embossed patterns on it; (c) subjecting the cloth with embossed patterns to a surface roughening treatment while maintaining the embossed patterns on the cloth; and (d) subjecting the surface-roughened cloth to a surface metalizing treatment.

The embossed conductive cloth obtained from the method of the present invention has excellent metal adhesion.

### FIELD OF THE INVENTION

The present invention belongs to the technical field of conductive cloth. Especially, the present invention relates to a method for manufacturing embossed conductive cloth with embossed patterns, identification characteristics of the cloth per se, and excellent metal adhesion.

### BACKGROUND OF THE INVENTION

Nowadays, techniques for manufacturing conductive cloth involve subjecting cloth to an electroless plating to form a metallized fabric. Common cloth comprises, for example, woven fabrics (e.g., plain-woven fabrics, solid check fabrics, twill fabrics, satin-woven fabrics, and oxford fabrics), knitted fabrics (e.g., circular knit fabrics, warp knits, weft or filling knits), nonwoven fabrics (e.g., water-jet fabrics and needle fabrics) or net cloth. However, metallization of the surface of conductive cloth tends to result in a dull appearance and make it difficult to identify the cloth.

Hot roller pressing or embossing is usually utilized to provide gloss or embossed patterns on the surface of conductive cloth. However, such techniques tend to destroy the thin metal film on the surface of conductive cloth and cause discontinuity of the thin metal film. As a consequence, the conductivity, metal adhesion, texture and weather resistance of conductive cloth are influenced. Moreover, in the electromagnetic interference (EMI) shielding application, small metal pieces falling from conductive cloth tend to cause a short circuit or reduce the EMI shielding efficacy thereof.

There is a need for conductive cloth which can overcome the above-mentioned disadvantages.

### SUMMARY OF THE INVENTION

The present invention provides a method for manufacturing embossed conductive cloth which overcomes the above-mentioned disadvantages.

### DETAILED DESCRIPTION OF THE INVENTION

The present invention provides a method for manufacturing embossed conductive cloth which overcomes the above-mentioned disadvantages. The embossed conductive cloth made with the method of the present invention have desired embossed patterns, identification characteristics of the cloth per se, and excellent metal adhesion. As used herein, the phrase “identification characteristics of the cloth per se” means that specific embossed patterns are formed on conductive cloth so that the cloth has the desired mark or identification. Without embossed patterns on the surfaces, conductive cloth usually has similar appearance. The mark or identification on conductive cloth can be various embossed patterns, for example, “FTC” (a company name), “M2PTEX® e” (a trademark), lines, images of flowers or animals, or symbols.

Especially, the present invention provides a method for manufacturing an embossed conductive cloth, which comprises:
(a) providing a cloth made of natural fibers or artificial fibers,
(b) embossing the cloth to form embossed patterns on it;
(c) subjecting the cloth with embossed patterns to a surface roughening treatment while maintaining the embossed patterns on the cloth; and
(d) subjecting the surface-roughened cloth to a surface metalizing treatment.

In step (a), the natural fiber can be any natural fiber, which includes, but is not limited to, cotton, linen, silk, and wool. The artificial fiber can be any artificial fiber, which includes, but is not limited to, rayon, nylon, polyester, and acrylics. Preferably, the artificial fiber is polyester. The cloth can be made in any weaving form, which includes, but is not limited to, a woven fabric, a knit fabric, a nonwoven fabric, and net cloth.

Step (b) can be carried out by using any conventional embossing device, which includes, but is not limited to, a roller embosser having predetermined embossed patterns. Preferably, the embossing step is carried out in the following manner: feeding cloth to a proper position by using a fabric guider, controlling the strength of the cloth by using a strength controller, and then embossing the cloth by using a roller embosser containing a rubber roll and a stainless sculptured roll having predetermined embossed patterns. The rollers are arranged properly. For example, they can be arranged in the following manner: a rubber roll (diameter: 360-400 mm) is placed underneath and a stainless sculptured roll (diameter: 190-250 mm) is placed on top. Temperature control is carried out through the stainless sculptured roll.

There is no particular limitation on the operating conditions of step (b). According to a preferred embodiment of the invention, step (b) is carried out under the following operating conditions:
Temperature: about 20° C. to about 230° C., preferably about 25° C. to about 190° C.
Pressure: about 5 kg/cm² to about 100 kg/cm², preferably about 10 kg/cm² to about 50 kg/cm²
Speed of embosser: about 5 M/min to about 80 M/min, preferably about 10 M/min to about 50 M/min

According to a preferred embodiment of the invention, after step (b), embossed patterns having a curve depth of about 1 μm to about 500 μm, preferably about 10 μm to about 100 μm, are formed on the cloth. Optionally, the embossed patterns can be lines, figures, decorative designs, or symbols.

Step (c) can be carried out by using any conventional surface roughening technique, which can be, for example, reduction of the weight of the cloth by an alkali treatment so as to form numerous uniform micro-pores on the surface of the cloth, or a plasma treatment. Preferably, step (c) is carried out by reducing the weight of the cloth via an alkali treatment. The rate of weight reduction can be about 5% to about 40%, preferably about 10% to about 30%. The weight reduction can be carried out, for example, in a continuous weight reduction machine or a high temperature dye jigger.

When a continuous weight reduction machine (L-BOX) is used, the weight reduction can be carried out under the following conditions:
Reagent: an aqueous solution of sodium hydroxide, 2% to 40%
Pick Up rate: 10% to 200%
Reaction temperature: 80° C. to 110° C.
Reaction time: 1 minute to 20 minutes

When a high temperature dye jigger is used, the weight reduction can be carried out under the following conditions:
Reagent: an aqueous solution of sodium hydroxide, 2% to 40%
Ratio of liquids: 1:0.5 to 1:30
Reaction temperature: 80° C. to 135° C.
Reaction time: 5 minutes to 20 minutes

Step (d) can be carried out by using any conventional metallization technique, which can be, for example, evaporating, sputtering, electroplating, and electroless plating. Preferably, step (d) is carried out through electroless plating.

Preferably, before being subjected to a surface metalizing treatment, the cloth is subjected to a surface conditioning treatment using any conventional conditioning technique. A known surface conditioning technique is to dip the cloth in a surfactant. There is no special limitation on the surfactant suitable for a surface conditioning treatment. Preferably, a cationic surfactant, for example, a quaternary ammonium salt, chitin, and ethanolamine salt, is used.

Generally, evaporating is carried out by placing the cloth within a vacuum chamber having a pressure, for example, from 0.0001 torr to 0.1 torr, adding to the chamber a proper metal, which can be, for example, copper, nickel, silver, gold, iron, cobalt, an alloy or a mixture thereof, atomizing the metal at an elevated temperature (e.g., from 800° C. to 1500° C.), and then drastically cooling the cloth to form surface-metallized cloth.

Sputtering is carried out by placing the cloth within a vacuum chamber having a pressure, for example, of 0.0001 torr to 0.1 torr, introducing a proper gas, which can be, for example, nitrogen, oxygen, argon, or a mixture thereof, into the chamber. A direct current, a radio frequency, or a microwave with a power, for example, of 50 W to 1000 W, is used to excite plasma. The resulted plasma is sputtered onto a metal target to allow a metal, which can be, for example, copper, nickel, silver, gold, iron, cobalt, an alloy or a mixture thereof, to be sputtered on the surface of the cloth so as to form a surface-metallized cloth.

Plating is carried out by placing the cloth on a cathode, in which the cloth is dipped in an electrolyte containing the metal ions to be plated. A corresponding pure metal is used as an anode. After a current is applied, the desired metal ions can be plated on the cloth. Moreover, electroless plating is carried out by dipping the cloth in a solution for electroless plating and plating a desired metal on the cloth using a controlled, automatically catalyzing reduction method. Metals suitable for use in electroless plating can be any metal having good conductivity, which can be, for example, a metal selected from the group consisting of copper, nickel, silver, gold, iron, cobalt, an alloy and a mixture thereof. Preferably, an initial copperization of the cloth is carried out by electroless copper plating so as to provide the cloth with conductivity, and a subsequent metallization is carried out by copper plating or electroless copper plating.

According to a preferred embodiment of the present invention, the metallization on the surface of the cloth is carried out in the following manner:
Dipping in a surfactant→Rinsing→Pre-dipping→Catalyzing→Rinsing→Accelerating→Rinsing→Electroless copper plating→Rinsing→Nickelizing (Nickel plating or Electroless nickel plating)→Rinsing→Drying→Final product.

Preferably, prior to the embossing step (step (b)), the method of the present invention further comprises the steps of desizing and finishing, rinsing, and thermal setting to keep the cloth clean and maintain the dimensional stability thereof. The steps of desizing and finishing, rinsing, and thermal setting can be carried out by using any conventional technique, which can be, but is not limited to, at the following conditions:
Machine: stressless, continuous desizing and finishing machine
Speed of machine: 10 M/min to 100 M/min
Reagents: sodium hydroxide (0.1 g/L to 50 g/L) plus a chelating dispersant (0.1 g/L to 20 g/L) plus a finishing agent (0.1 g/L to 30 g/L)
Retention time within reaction chamber: 5 minutes to 30 minutes
Temperature of reaction chamber: 70° C. to 100° C.
Rinsing with warm water (30° C. to 80° C.): 1 minute to 10 minutes
   Thermal setting is carried out by using a thermal setting machine under the following conditions:
Temperature: 160° C. to 200° C.
Speed of machine: 20 M/min to 120 M/min

In the method of the present invention, the cloth is embossed to form embossed patterns thereon and then subjected to a surface-roughening treatment (e.g., by weight reduction). By doing so, numerous uniform micro-pores are formed on the surface of the cloth. As a consequence, metal targeting efficacy during metallization is enhanced and metal adhesion is increased. After the above-mentioned steps, the cloth is subjected to metallization through electroless plating so that embossed conductive cloth with desired embossed patterns, identification characteristics of the cloth per se, excellent metal adhesion, soft texture, and good weather resistance is obtained.

Usually, to facilitate end-use processing, a conventional conductive pressure-sensitive adhesive gel and release paper can be adhered to or coated on the surface (either side) of the embossed conductive cloth of the present invention to form a conductive cloth tape. The conductive cloth tape can be cut and rolled up or just left as a sheet. Besides, the conductive cloth of the present invention can be prepared as a conductive cloth lining or a conductive cloth shaping material.

Because the embossed conductive cloth of the present invention has excellent metal adhesion, it provides an EMI shielding efficacy and can protect humans against the damage of electromagnetic wave from electric machines, base stations, household appliances, or industrial facilities or prevent industrial facilities from the interference of electromagnetic waves or from mistaken operation. For applications, the embossed conductive cloth of the present invention can be produced as, for example, EMI shielding curtains, EMI shielding materials for wall decoration, and EMI shielding clothes.

### EXAMPLES

The invention will become apparent with reference to the following examples, which are purely for illustrative purpose, and should in no way limit the scope of the invention as described in the claims.

### Example 1

Embossed conductive plain-woven cloth was produced in the following manner:
1. Weaving: A polyester fiber which was made of a warp yarn of 50 denier/36 fiber number and a weft yarn of 50 denier/36 fiber number and had a warp density of 150 threads/inch and a weft density of 120 threads/inch was used to plain weave cloth having a thickness of 0.1 mm.
2. Desizing and finishing, rinsing, and thermal setting the plain-woven cloth:
   Desizing and finishing/rinsing:
      Speed of machine: 50 M/min
      Retention time within reaction chamber: 10 minutes
      Reagents: sodium hydroxide (5 g/L) plus a chelating dispersant (1 g/L) plus a finishing agent (2 g/L)
      Temperature of reaction chamber: 85° C.
      Rinsing with warm water (50° C.): 3 minutes
   Thermal setting:
      Speed of machine: 50 M/min
      Temperature: 190° C.
      Time: 30 seconds
3. Embossing: The plain-woven cloth was embossed by a embosser at a temperature of 180° C., a pressure of 40 kg/cm², and a speed of 30 M/min, to form embossed patterns on the cloth.
4. Surface roughening: The plain-woven cloth was dipped in an aqueous solution of sodium hydroxide (20%) at 80° C. for 15 minutes for weight reduction. The rate of weight reduction was 15% to 25%. Thereafter, the cloth was rinsed with water.
5. Surface conditioning: The plain-woven cloth was dipped in a cationic surfactant (ethanolamine salt, 5 g/L) at 100° C. for 3 minutes, and then rinsed completely.
   Pre-dipping: The plain-woven cloth was dipped in a hydrogen chloride solution (100 ml/L) at 30° C. for 1 minute.
   Catalyzing: The plain-woven cloth was dipped in a solution comprising palladium chloride (100 mg/L), stannous chloride (10 g/L), and hydrogen chloride (100 ml/L) at 30° C. for 3 minutes, and then rinsed completely.
   Accelerating: The plain-woven cloth was dipped in a hydrogen chloride solution (100 ml/L) at 45° C. for 3 minutes, and then rinsed completely.
6. Electroless copper plating: The plain-woven cloth was dipped in a solution comprising copper sulfate (10 g/L), formaldehyde (7.5 ml/L), sodium hydroxide (8 g/L), ethylene diamine tetraacetic acid tetrasodium salt (EDTA-4Na) (30 g/L), and a stabilizer (0.25 ml/L) at 40° C. for 20 minutes, in order to plate metal copper on the plain-woven cloth evenly, and then rinsed completely.
7. Electroless nickel plating: The plain-woven cloth was dipped in a solution comprising nickel sulfate (22.5 g/L), sodium hypophosphite (18 g/L), sodium citrate (0.1 M/L), and ammonia water (20 ml/L) at 40° C. for 5 minutes, in order to plate metal nickel (5 g/M2) on the plain-woven cloth evenly. The plain-woven cloth was then rinsed completely and dried to obtain embossed conductive plain-woven cloth.

### Example 2

Embossed conductive plain-woven cloth was produced according to the following manner:
1. Weaving: A polyester fiber which was made of a warp yarn of 50 denier/36 fiber number and a weft yarn of 50 denier/36 fiber number and had a warp density of 150 threads/inch and a weft density of 120 threads/inch was used to plain weave cloth having a thickness of 0.1 mm.
2. Desizing and finishing, rinsing, and thermal setting the plain-woven cloth:
   Desizing and finishing/rinsing:
      Speed of machine: 50 M/min
      Retention time within reaction chamber: 10 minutes
      Reagents: sodium hydroxide (5 g/L) plus a chelating dispersant (1 g/L) plus a finishing agent (2 g/L)
      Temperature of reaction chamber: 85° C.
      Rinsing with warm water (50° C.): 3 minutes
   Thermal setting:
      Speed of machine: 50 M/min
      Temperature: 190° C.
      Time: 30 seconds
3. Embossing: The plain-woven cloth was embossed by a embosser at a temperature of 30° C., a pressure of 15 kg/cm², and a speed of 30 M/min, to form embossed patterns on the cloth.
4. Surface roughening: The plain-woven cloth was dipped in an aqueous solution of sodium hydroxide (20%) at 80° C. for 15 minutes for weight reduction. The rate of weight reduction was 15% to 25%. Thereafter, the cloth was rinsed with water.
5. The plain-woven cloth was metallized by electroless plating in the same manner described in steps 5 to 7 of Example 1 to obtain embossed conductive plain-woven cloth.

### Example 3

Embossed conductive solid check cloth was produced in the following manner:
1. Weaving: A polyester fiber, which was made of a warp yarn of 50 denier/36 fiber number and a weft yarn of 50 denier/72 fiber number and had a warp density of 148 threads/inch and a weft density of 118 threads/inch was used to weave solid check cloth having a thickness of 0.11 mm.
2. Desizing and finishing, rinsing, and thermal setting the solid check cloth:
   Desizing and finishing/rinsing:
      Speed of machine: 50 M/min
      Retention time within reaction chamber: 10 minutes
      Reagents: sodium hydroxide (5 g/L) plus a chelating dispersant (1 g/L) plus a finishing agent (2 g/L)
      Temperature of reaction chamber: 85° C.
      Rinsing with warm water (50° C.): 3 minutes
   Thermal setting:
      Speed of machine: 50 M/min
      Temperature: 190° C.
      Time: 30 seconds
3. Embossing: The solid check cloth was embossed by a embosser at a temperature of 35° C., a pressure of 15 kg/cm², and a speed of 30 M/min, to form embossed patterns on the cloth.
4. Surface roughening: The solid check cloth was dipped in an aqueous solution of sodium hydroxide (25%) at 90° C. for 15 minutes for weight reduction. The rate of weight reduction was from 15% to 25%. Thereafter, the cloth was rinsed with water.
5. The solid check cloth was metallized by clectToless plating in the same manler described in steps 5 to 7 of Example 1 to obtain embossed conductive solid check cloth.

### Example 4

Embossed conductive nonwoven cloth was produced in the following manner:
1. Composite polyester fibrous nonwoven cloth was produced by pressing high temperature hot-melting adhesive gel dots on fibers so that the dots adhered to the facial fibers in order to increase the stress at rupture. The cloth had a weight of 55 G/M2, a thickness of 0.25 mm, a single fiber of 2 denier, and a fiber length of 51 mm. Essential components of the composite polyester fiber include: a polyester fiber having a low melting point (melting point: 190° C.) in an amount of 35% by weight as the outer layer, and a polyester fiber having a regular melting point (melting point: 245° C.) in an amount of 75% by weight as the inner layer.
2. Desizing and finishing, rinsing, and thermal setting the nonwoven cloth:
   Desizing and finishing/rinsing:
      Speed of machine: 50 M/min
      Retention time within reaction chamber: 10 minutes
      Reagents: sodium hydroxide (5 g/L) plus a chelating dispersant (1 g/L) plus a finishing agent (2 g/L)
      Temperature of reaction chamber: 85° C.
      Rinsing with warm water (50° C.): 3 minutes
   Thermal setting:
      Speed of machine: 50 M/min
      Temperature: 190° C.
      Time: 37 seconds
3. Embossing: The nonwoven cloth was embossed by a embosser at a temperature of 35° C., a pressure of 15 kg/cm², and a speed of 30 M/min, to form embossed patterns on the cloth.
4. Surface roughening: The nonwoven cloth was dipped in an aqueous solution of sodium hydroxide (25%) at 90° C. for 15 minutes for weight reduction. The rate of weight reduction was 15% to 25%. Thereafter, the cloth was rinsed with water.
5. The nonwoven cloth was metallized by electroless plating in the same manner described in steps 5 to 7 of Example 1 to obtain embossed conductive nonwoven cloth.

### Example 5

Embossed conductive net cloth was produced in the following manner:
1. Embossed conductive net cloth was produced by using 135 MESH Count and each of warp yarn and weft yarn( ) was in an amount of 135 threads/(inch)². The net cloth had a thickness of 0.09 mm.
2. Desizing and finishing, rinsing, and thermal setting the net cloth:
   Desizing and finishing/rinsing:
      Speed of machine: 50 M/min
      Retention time within reaction chamber: 10 minutes
      Reagents: sodium hydroxide (5 g/L) plus a chelating dispersant (1 g/L) plus a finishing agent (2 g/L)
      Temperature of reaction chamber: 85° C.
      Rinsing with warm water (50° C.): 3 minutes
   Thermal setting:
      Speed of machine: 50 M/min
      Temperature: 190° C.
      Time: 37 seconds
3. Embossing: The net cloth was embossed by a embosser at a temperature of 35° C., a pressure of 15 kg/cm², and a speed of 30 M/min, to form embossed patterns on the cloth.
4. Surface roughening: The net cloth was dipped in an aqueous solution of sodium hydroxide (25%) at 90° C. for 15 minutes for weight reduction. The rate of weight reduction was 15% to 25%. Thereafter, the cloth was rinsed with water.
5. The net cloth was metallized by electroless plating in the same manner described in steps 5 to 7 of Example 1 to obtain embossed conductive net cloth.

### Example 6

Embossed conductive knit cloth was produced according to the following manner:
1. Embossed conductive knit cloth was produced by circular knitted fibers. The warp and weft yarns were processing yarns of 75 denier/fiber number. The knit cloth had a weight of 62 G/M2 and a thickness of 0.28 mm.
2. Desizing and finishing, rinsing, and thermal setting the knitted cloth:
   Desizing and finishing/rinsing:
      Speed of machine: 50 M/min
      Retention time within reaction chamber: 10 minutes
      Reagents: sodium hydroxide (5 g/L) plus a chelating dispersant (1 g/L) plus a finishing agent (2 g/L)
      Temperature of reaction chamber: 85° C.
      Rinsing with warm water (50° C.): 3 minutes
   Thermal setting:
      Speed of machine: 50 M/min
      Temperature: 190° C.
      Time: 37 seconds
3. Embossing: The knitted cloth was embossed by a embosser at a temperature of 35° C., a pressure of 15 kg/cm², and a speed of 30 M/min, to form embossed patterns on the cloth.
4. Surface roughening: The knitted cloth was dipped in an aqueous solution of sodium hydroxide (25%) at 90° C. for 15 minutes for weight reduction. The rate of weight reduction was 15% to 25%. Thereafter, the cloth was rinsed with water.
5. The knit cloth was metallized by electroless plating in the same manner described in steps 5 to 7 of Example 1 to obtain an embossed conductive knit cloth.

### Example 7

Embossed conductive plain-woven cloth was produced in the following manner:
1. A composite polyester fiber, which was made of a warp yarn of 75 denier/36 fiber number and a weft yarn of 75 denier/36 fiber number and had a warp density of 120 threads/inch and a weft density of 90 threads/inch was used to plain weave cloth having a thickness of 0.12 mm,
   Essential components of the composite polyester fiber include: a polyester fiber having a low melting point (melting point: 190° C.) in an amount of 35% by weight as the outer layer, and a polyester fiber having a regular melting point (melting point: 245° C.) in an amount of 75% by weight as the inner layer.
2. Desizing and finishing, rinsing, and thermal setting the plain-woven cloth:
   Desizing and finishing/rinsing:
      Speed of machine: 50 M/min
      Retention time within reaction chamber: 10 minutes
      Reagents: sodium hydroxide (5 g/L) plus a chelating dispersant (1 g/L) plus a finishing agent (2 g/L)
      Temperature of reaction chamber: 85° C.
      Rinsing with warm water (50° C.): 3 minutes
   Thermal setting:
      Speed of machine: 50 M/min
      Temperature: 190° C.
      Time: 30 seconds
3. Embossing: The plain-woven cloth was embossed by a embosser at a temperature of 180° C., a pressure of 40 kg/cm², and a speed of 30 M/min, to form embossed patterns on the cloth.
4. Surface roughening: The plain-woven cloth was dipped in an aqueous solution of sodium hydroxide (20%) at 80° C. for 15 minutes for weight reduction. The rate of weight reduction was 15% to 25%. Thereafter, the cloth was rinsed with water.
5. The plain-woven cloth was metallized by electroless plating in the same manner described in steps 5 to 7 of Example 1 to obtain embossed conductive plain-woven cloth.

### Comparative Example 1

Embossed conductive plain-woven cloth was produced in the following manner:
1. Weaving: A polyester fiber which was made of a warp yarn of 50 denier/36 fiber number and a weft yarn of 50 denier/36 fiber number and had a warp density of 150 threads/inch and a weft density of 120 threads/inch, was used to plain weave cloth having a thickness of about 0.1 mm.
2. Desizing and finishing, rinsing, and thermal setting the plain-woven cloth:
   Desizing and finishing/rinsing:
      Speed of machine: 50 M/min
      Retention time within reaction chamber: 10 minutes
      Reagents: sodium hydroxide (5 g/L) plus a chelating dispersant (1 g/L) plus a finishing agent (2 g/L)
      Temperature of reaction chamber: 85° C.
      Rinsing with warm water (50° C.): 3 minutes
   Thermal setting:
      Speed of machine: 50 M/min
      Temperature: 190° C.
      Time: 30 seconds
3. Surface roughening: The plain-woven cloth was dipped in an aqueous solution of sodium hydroxide (20%) at 80° C. for 15 minutes for weight reduction. The rate of weight reduction was from 15% to 25%. Thereafter, the cloth was rinsed with water.
4. The plain-woven cloth was metallized by electroless plating in the same manner described in steps 5 to 7 of Example 1 to obtain embossed conductive plain-woven cloth.
5 Embossing: The plain-woven cloth was embossed by a embosser at a temperature of 180° C., a pressure of 40 kg/cm², and a speed of 30 M/min, to form embossed patterns on the cloth.

### Comparative Example 2

Embossed conductive plain-woven cloth was produced in the following manner:
1. Weaving: A polyester fiber which was made of a warp yarn of 50 denier/36 fiber number and a weft yarn of 50 denier/36 fiber number and had a warp density of 150 threads/inch and a weft density of 120 threads/inch, was used to plain weave cloth having a thickness of about 0.1 mm.
2. Desizing and finishing, rinsing, and thermal setting the plain-woven cloth:
   Desizing and finishing/rinsing:
      Speed of machine: 50 M/min
      Retention time within reaction chamber: 10 minutes
      Reagents: sodium hydroxide (5 g/L) plus a chelating dispersant (1 g/L) plus a finishing agent (2 g/L)
      Temperature of reaction chamber: 85° C.
      Rinsing with warm water (50° C.): 3 minutes
   Thermal setting:
      Speed of machine: 50 M/min
      Temperature: 190° C.
      Time: 30 seconds
3. Surface roughening. The plain-woven cloth was dipped in an aqueous solution of sodium hydroxide (20%) at 80° C. for 15 minutes for weight reduction. The rate of weight reduction was 15% to 25%. Thereafter, the cloth was rinsed with water.
4. The plain-woven cloth was metallized by electroless plating in the same manner described in steps 5 to 7 of Example 1 to obtain embossed conductive plain-woven cloth.
5. Embossing: The plain-woven cloth was embossed by a embosser at a temperature of 35° C., a pressure of 15 kg/cm², and a speed of 30 M/min, to form embossed patterns on the cloth.

### Comparative Example 3

Embossed conductive plain-woven cloth was produced in the following manner:
1. Weaving: A polyester fiber which was made of a warp yarn of 50 denier/36 fiber number and a weft yarn of 50 denier/36 fiber number and had a warp density of 150 threads/inch and a weft density of 120 threads/inch, was used to plain weave cloth having a thickness of about 0.1 mm.
2. Desizing and finishing, rinsing, and thermal setting the plain-woven cloth:
   Desizing and finishing/rinsing:
      Speed of machine: 50 M/min
      Retention time within reaction chamber: 10 minutes
      Reagents: sodium hydroxide (5 g/L) plus a chelating dispersant (1 g/L) plus finishing agent (2 g/L)
      Temperature of reaction chamber: 85° C.
      Rinsing with warm water (50° C.): 3 minutes
   Thermal setting:
      Speed of machine: 50 M/min
      Temperature: 190° C.
      Time: 30 seconds
3. Surface roughening: The plain-woven cloth was dipped in an aqueous solution of sodium hydroxide (20%) at 80° C. for 15 minutes for weight reduction. The rate of weight reduction was 15% to 25%. Thereafter, the cloth was rinsed with water.
4. Embossing: The plain-woven cloth was embossed by a embosser at a temperature of 35° C., a pressure of 15 kg/cm², and a speed of 30 M/min, to form embossed patterns on the cloth.
5. The plain-woven cloth was metallized by electroless plating in the same manner described in steps 5 to 7 of Example 1 to obtain plain-woven embossed conductive plain-woven cloth.

### Tests and Results

The embossed conductive cloth obtained from examples 1 to 7 and comparative examples 1 to 3 were subjected to various tests of their physical properties in the following manners and under the following conditions:
1. Surface resistance (Ω/) test: The resistance of the cloth along horizontal orientation was tested.
   A 10 cm×10 cm sample of conductive cloth was used as a sample. The test was conducted according to JIS K-7194 standard using the machine Mitsubish Loresta MCP-T600. A 4-point-probe test was carried out. The probe was horizontally pressed on the surface of the conductive cloth sample and a stable value of surface resistance was recorded.
2. Environment test: The weather resistance of the cloth was tested.
   Temperature, relative humidity (RH) and time (hour, hr) for carrying out the test were listed below:

50° C.*80% RH*5 HRS→90° C.*90% RH*10 HRS→120° C.*5 HRS→20° C.*50% RH*5 HRS→−15° C.*10 HRS→40° C.*65% RH*5 HRS
The test was repeated 5 times in a row. The color change of the appearance of the conductive cloth sample was observed and recorded according to the following standards:
O: almost no color change observed in the appearance,
Δ: only slight color change and oxidation observed in the appearance,
X: serious color change and oxidation observed in the appearance.

### 3. Metal Adhesion:

A 3M 610 tape having a width of 1.9 cm and a length of 15 cm was attached to the surface of the conductive cloth sample. A stainless roller having a weight of 2 kg was rolled on the sample 10 times back and forth. The 3M 610 tape was removed from the surface of the sample quickly. The quantity of the metal powder adhered to the tape was observed and recorded according to the following standards for determining the level of metal adhesion:
Level 1: a large amount of metal powder was observed,
Level 2: a small amount of metal powder spreading all over the surface of the tape was observed,
Level 3: a small amount of metal powder spreading on a part of the surface of the tape was observed,
Level 4: an extremely small amount of metal powder was observed,
Level 5: almost no metal powder was observed.

### 4. EMI Shielding Value (dB Value):

A 13.2 cm×13.2 cm sample of conductive cloth was used for test. The test was conducted according to ASTM D4935 standard using the machine Agilent Vector Network Analyzer (E5062A). The frequency for the test ranged from 300 kHz to 3 GHz. The sample for the EMI shielding test was put in a conical copper metal instrument having an inner diameter of 7.6 cm and an outer diameter of 13.2 cm. The EMI shielding value (dB value) was 20 log (Ei/Et) dB. Ei is the strength of electronic field of an incident wave (volts/m) and Et is the strength of electronic field of a transmitted wave (volts/m).

The data of the tests on the physical properties of the embossed conductive cloth obtained from examples 1 to 7 and comparative examples 1 to 3 was shown in Table 1.

TABLE 1

| | | | | EMI | |
|---|---|---|---|---|---|
| | | | | shielding | |
| | Surface | | Metal | value (dB | |
| | resistance | Weather | adhesion | value) | Overall |
| | (Ω/□) | resistance | (level) | (at 1 GHz) | Evaluation |
| Example 1 | 0.02 | ◯ | 4 | 80 | Excellent |
| Example 2 | 0.02 | ◯ | 5 | 80 | Excellent |
| Example 3 | 0.02 | ◯ | 5 | 80 | Excellent |
| Example 4 | 0.02 | ◯ | 5 | 87 | Excellent |
| Example 5 | 0.02 | ◯ | 5 | 80 | Excellent |
| Example 6 | 0.02 | ◯ | 5 | 85 | Excellent |
| Example 7 | 0.02 | ◯ | 4 | 85 | Excellent |
| Comparative | 0.03 | X | 1 | 50 | Poor |
| Example 1 | | | | | |
| Comparative | 0.03 | X | 1 | 50 | Poor |
| Example 2 | | | | | |
| Comparative | 0.02 | Δ | 2 | 50 | Poor |
| Example 3 | | | | | |

What is claimed is:

1. A method for manufacturing embossed conductive cloth, which comprises:
(a) providing a cloth made of natural fibers or artificial fibers,
(b) embossing the cloth to form embossed patterns on it;
(c) subjecting the cloth with embossed patterns to a surface roughening treatment while maintaining the embossed patterns on the cloth; and
(d) subjecting the surface-roughened cloth to a surface metalizing treatment.

2. The method according to claim 1, wherein the natural fiber comprises cotton, linen, silk, and wool, and the artificial fiber comprises rayon, nylon, polyester, and acrylics.

3. The method according to claim 1, wherein the cloth is a woven fabric, a knit fabric, a nonwoven fabric, or net cloth.

4. The method for manufacturing according to claim 1, wherein step (b) is carried out under the following operating conditions:
temperature: about 20° C. to about 230° C.
pressure: about 5 kg/cm² to about 100 kg/cm²
speed of embosser: about 5 M/min to about 80 M/min.

5. The method according to claim 4, wherein step (b) is carried out under the following operating conditions:
temperature: about 25° C. to about 190° C.
pressure: about 10 kg/cm² to about 50 kg/cm²
speed of embosser: about 10 M/min to about 50 M/min.

6. The method according to claim 1, wherein after step (b) is carried out, embossed patterns having a curve depth of about 1 μm to about 500 μm are formed on the cloth.

7. The method according to claim 6, wherein after step (b) is carried out, embossed patterns having a curve depth of about 10 μm to about 100 μm are formed on the cloth.

8. The method according to claim 1, wherein step (c) is carried out by reducing the weight of the cloth via an alkali treatment and the rate of weight reduction is about 5% to about 40%.

9. The method according to claim 8, wherein the rate of weight reduction is about 10% to about 30%.

10. The method according to claim 8, wherein the weight reduction is carried out in a continuous weight reduction machine or a high temperature dye jigger.

11. The method according to claim 1, wherein step (d) is carried out by plating a metal selected from the group consisting of copper, nickel, silver, gold, iron, cobalt and an alloy or a mixture thereof on the surface of the cloth.

12. The method according to claim 1, wherein step (d) is carried out by evaporating, sputtering or electroplating.

13. The method according to claim 1, wherein step (d) is carried out by conducting a initial copperization using electroless copper plating and then conducting a subsequent nickelization using electro nickel plating or electroless nickel plating.

14. The method according to claim 1, which, prior to step (b), further comprises the steps of desizing and finishings rinsing, and thermal setting the cloth.
